(19) United States
(12) Patent Application Publication
(10) Pub. No.: US 2015/0188066 A1
(43) Pub. Date: Jul. 2, 2015

(54) WHITE ORGANIC LIGHT EMITTING DEVICE

(71) Applicant: LG Display Co., Ltd., Seoul (KR)

(72) Inventors: Ki-Woog SONG, Goyang-si (KR); Tae-Il KUM, Paju-si (KR); Shin-Han KIM, Seoul (KR); Seon-Keun YOO, Gunpo-si (KR); Hee-Dong CHOI, Uiwang-si (KR); Chi-Yul SONG, Seoul (KR)

(73) Assignee: LG Display Co., Ltd., Seoul (KR)

(21) Appl. No.: 14/563,607

(22) Filed: Dec. 8, 2014

(30) Foreign Application Priority Data
Dec. 31, 2013 (KR) 10-2013-0168250

(51) Int. Cl. H01L 51/50

(52) U.S. Cl. CPC H01L 51/504; H01L 51/5004; H01L 51/5056; H01L 51/5072; H01L 51/0052

(57) ABSTRACT

Discussed is a white organic light emitting device including an anode and a cathode opposite to each other, a plurality of stacks disposed between the anode and the cathode, each of the stacks including a hole transport layer, a light emitting layer and an electron transport layer, and a charge generation layer disposed between different stacks, the charge generation layer including a single organic host having an electron transport property, and an n-type dopant and a p-type dopant.

This application claims the benefit of Korean Patent Application No. 10-2013-0168250, filed on Dec. 31, 2013, which is hereby incorporated by reference as if fully set forth herein.

### BACKGROUND OF THE INVENTION

1. Field of the Invention

The present disclosure relates to an organic light emitting device and, more particularly, to a white organic light emitting device which does not increase a driving voltage, simplifies formation of a charge generation layer between stacks and improves efficiency and lifespan.

2. Discussion of the Related Art

In recent years, the coming of the information age has brought about rapid development in displays which visually express electrical information signals. In response to this, a great deal of research has been conducted to impart superior properties such as slimness, light weight and low power consumption to a variety of flat display devices.

Specifically, representative examples of the flat display devices include liquid crystal display (LCD) devices, plasma display panel (PDP) devices, electroluminescent display (ELD) devices, electrowetting display (EWD) devices, field emission display (FED) devices, organic light emitting diode (OLED) display devices and the like.

In common, the flat display devices necessarily include a flat display panel to form an image. The flat display panel has a structure in which a pair of substrates facing each other are joined such that an inherent light emitting material or polarizing material is disposed between the substrates.

Of these, organic light emitting display devices display images using organic light emitting diodes which autonomously emit light.

Hereinafter, a general organic light emitting device will be described.

The general organic light emitting device includes, as constituent components, a substrate, a first electrode and a second electrode disposed on the substrate such that the electrodes face each other, and a light emitting layer formed between the electrodes, and emits light based on driving current flowing between the first electrode and second electrode. The light emitting layer generates light via recombination of holes and electrons.

In addition, the organic light emitting device may further include a hole transport layer between the first electrode and the light emitting layer for easy transport of holes from the first electrode to the light emitting layer and an electron transport layer between the second electrode and the light emitting layer for easy transport of electrons from the second electrode to the light emitting layer.

In some cases, the hole transport layer may further include a hole injection layer adjacent to the first electrode and the electron transport layer may further include an electron injection layer adjacent to the second electrode. The hole injection layer may be formed integrally with or separately from the hole transport layer and the electron injection layer may be also formed integrally with or separately from the electron transport layer.

Components for layers provided in the first electrode and the second electrode are organic substances and these organic substance layers are formed by sequentially depositing components for the corresponding layers on the substrate.

Formation of an organic light emitting layer is required for such an organic light emitting display device.

Organic light emitting display devices which exhibit white color by laminating a stack structure including different colors of organic light emitting layers, instead of patterning the organic light emitting layers on a pixel basis, are suggested.

That is, organic light emitting display devices are produced by depositing respective layers between an anode and a cathode without using a mask in the formation of light emitting diodes. The organic light emitting display devices are characterized in that organic films including organic light emitting layers are sequentially formed by depositing different components for the films under vacuum.

The organic light emitting display devices may be utilized in a variety of applications including slim light sources, backlights of liquid crystal display devices or full-color display devices using color filters.

Meanwhile, conventional organic light emitting display devices include a plurality of stacks emitting different colors of light wherein each of the stacks includes a hole transport layer, a light emitting layer and an electron transport layer. In addition, each light emitting layer includes a single host and a dopant for rendering color of emitted light, to emit the corresponding color of light based on recombination of electrons and holes injected into the light emitting layer. In addition, a plurality of stacks, each including different colors of light emitting layers, are formed by lamination. In this case, a charge generation layer (CGL) is formed between the stacks so that electrons are received from the adjacent stack or holes are transported thereto. In addition, the charge generation layer is divided into an n-type charge generation layer and a p-type charge generation layer. A conventional charge generation layer structure capable of improving both driving voltage and lifespan has not yet reported.

In a laminate structure including a plurality of stacks, a charge generation layer is disposed as a layer for connecting the stacks and includes two layers, i.e., an n-type charge generation layer and a p-type charge generation layer which are laminated. In this case, electrons are accumulated at the interface between the n-type charge generation layer and the p-type charge generation layer, thus disadvantageously making transfer of electrons from the p-type charge generation layer to the n-type charge generation layer difficult, increasing an energy barrier of electron transport and increasing a driving voltage.

In addition, accumulation of electrons makes generation of holes difficult and thus bothers supply of holes to the stack adjacent to the p-type charge generation layer and, in the long view, causes deterioration in lifespan.

### SUMMARY OF THE INVENTION

Accordingly, the invention is directed to a white organic light emitting that substantially obviates one or more problems due to limitations and disadvantages of the related art.

An object of the invention is to provide a white organic light emitting device which does not increase a driving voltage, simplifies formation of a charge generation layer between stacks and improves efficiency and lifespan.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, a white organic light emitting device includes an anode and a cathode opposite to each other, a plurality of stacks disposed between the anode and the cathode, each of the stacks including a hole transport layer, a light emitting layer and an electron transport layer, and a charge generation layer disposed between different stacks, the charge generation layer including a single organic host having an electron transport property, and an n-type dopant and a p-type dopant.

The organic host may have a LUMO energy level of −3.5 eV to −2.0 eV and a HOMO energy level of −6.5 eV to −5.0 eV.

The organic host may have an electron mobility of 1.0×10⁻⁵ V·s/cm² to 5.0×10⁻³ V·s/cm².

The n-type dopant may be any one of an alkali metal, an alkaline earth metal, an alkali metal compound and an alkaline earth metal compound. Alternatively, the n-type dopant may serve as an electron donor and be an organic n-type dopant which forms a charge-transfer complex with the organic host.

The p-type dopant may serve as an electron acceptor and be an organic p-type dopant which forms a charge-transfer complex with the organic host.

The p-type dopant may be a radialene compound represented by the following Formula:

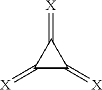

wherein X each independently represent

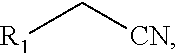

wherein R₁ are each independently selected from the group consisting of aryl and heteroaryl, wherein the aryl and heteroaryl are substituted by at least one electron acceptor group.

In this case, the electron acceptor group may be selected from cyano, fluoro, trifluoromethyl, chloro and bromo.

R₁ may be substituted by one of perfluoropyridin-4-yl, tetrafluoro-4-(trifluoromethyl)phenyl), 4-cyanoperfluorophenyl, dichloro-3,5-difluoror=4=(trifluoromethyl)phenyl, and perfluorophenyl.

The n-type dopant and the p-type dopant may be each formed in amounts of 0.1% to 15% by volume with respect to the total volume of the charge generation layer.

The p-type dopant may include metal oxide.

The p-type dopant may have a LUMO energy level between a HOMO energy level and a LUMO energy level of the organic host and a HOMO energy level lower than a HOMO energy level of the p-type organic host.

The charge generation layer may be disposed between a first stack and a second stack adjacent to each other, and the p-type dopant may be disposed in the charge generation layer such that the p-type dopant contacts the hole transport layer of the second stack, and the n-type dopant may be disposed in the charge generation layer such that the n-type dopant contacts the electron transport layer of the first stack.

If necessary, the p-type dopant and the n-type dopant may be disposed in the charge generation layer such that the p-type dopant overlaps the n-type dopant. Alternatively, the p-type dopant and the n-type dopant may be disposed in different regions in the charge generation layer such that the p-type dopant does not overlap the n-type dopant.

It is to be understood that both the foregoing general description and the following detailed description of the invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a sectional view illustrating a display device including a white organic light emitting device according to an embodiment of the invention;

FIG. 2 is a view illustrating an energy bandgap between a charge generation layer and a layer adjacent thereto in Reference Example compared with the white organic light emitting device according to an embodiment of the invention;

FIG. 3 is a view illustrating an energy bandgap between a charge generation layer and a layer adjacent thereto in a white organic light emitting device according to a first embodiment of the invention;

FIG. 4 is a view illustrating an energy bandgap between a charge generation layer and a layer adjacent thereto in a white organic light emitting device according to a second embodiment of the invention;

FIG. 5 is a graph showing comparison in lifespan between Reference Example and the first embodiment; and

FIG. 6 is a graph showing current efficacy according to luminance in Reference Example and the first embodiment.

### DETAILED DESCRIPTION OF THE INVENTION

Reference will now be made in detail to the preferred embodiments of the invention, examples of which are illustrated in the accompanying drawings. Wherever possible, the same reference numbers will be used throughout the drawings to refer to the same or like parts.

Hereinafter, a white organic light emitting device according to the invention will be described in detail with reference to the annexed drawings.

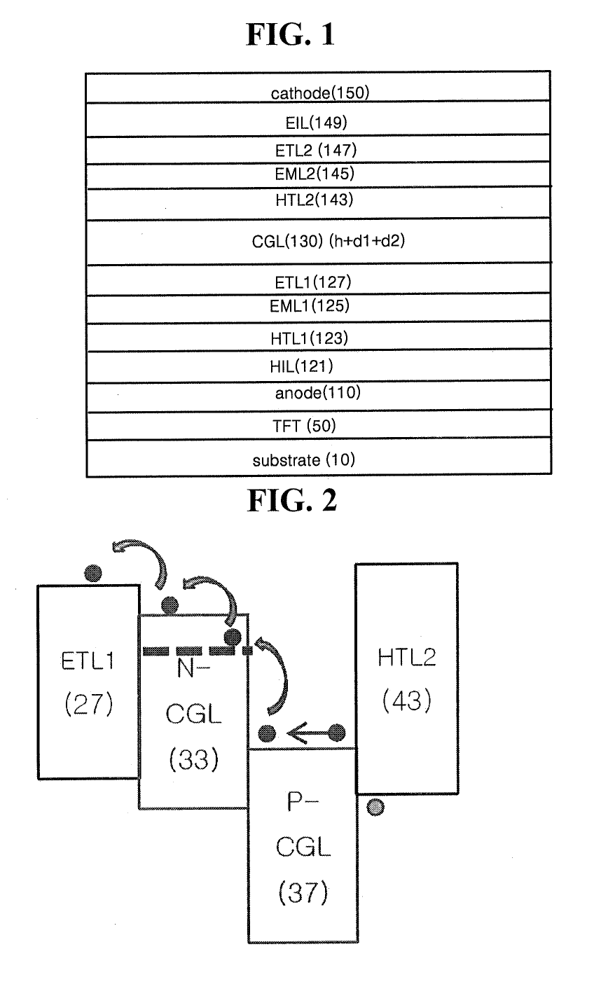

FIG. 1 is a sectional view illustrating a display device including a white organic light emitting device according to an embodiment of the invention.

As shown in FIG. 1, the display device including a white organic light emitting device according to the invention includes a thin film transistor array 50 including a plurality of thin film transistors TFTs forming a matrix on a substrate 10 and a white organic light emitting device connected to each thin film transistor TFT in each pixel.

In addition, the white organic light emitting device has n (wherein n is a natural number of 2 or more) stacks 120 and 140 interposed between an anode 110 and a cathode 150. Although only two stacks are shown in the drawing, the invention is not limited thereto and three or more stacks may be applied.

The stacks 120 and 140 disposed between the anode 110 and the cathode 150 respectively include hole transport layers 123 and 143, light emitting layers 125 and 145 and electron transport layers 127 and 147, and the first stack 120 adjacent to the anode 110 further includes a hole injection layer 121 contacting the anode 110 and the second stack adjacent to the cathode 150 further includes an electron injection layer 149 contacting the cathode 150.

In addition, a charge generation layer 130 including a single organic host material h and an n-type dopant d1 and a p-type dopant d2 which are different from each other between different stacks 120 and 140. Here, the organic host material h is a single compound having an electron transport property.

Preferably, the organic host h has a LUMO energy level of −3.5 eV to −2.0 eV and a HOMO energy level of −6.5 eV to −5.0 eV.

In this case, the organic host h is an electron-transporting compound having an electron mobility of 1.0×10⁻⁵ V·s/cm² to 5.0×10⁻³ V·s/cm².

For example, the organic host h may be a compound represented by any one of Formulae 1 to 3.

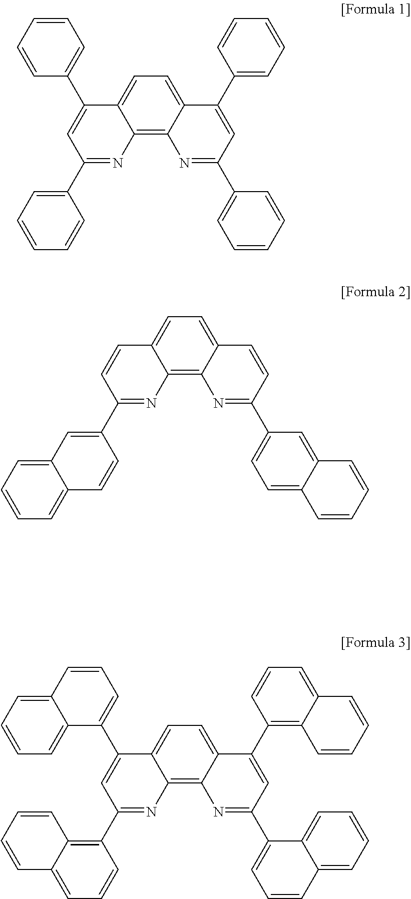 [SMILES: c1ccc(-c2cc(-c3ccccc3)c3ccc4c(-c5ccccc5)cc(-c5ccccc5)nc4c3n2)cc1 ; c1ccc2cc(-c3ccc4ccc5ccc(-c6ccc7ccccc7c6)nc5c4n3)ccc2c1 ; c1ccc2c(-c3cc(-c4cccc5ccccc45)c4ccc5c(-c6cccc7ccccc67)cc(-c6cccc7ccccc67)nc5c4n3)cccc2c1]

However, the organic host is not limited to compounds of Formulae 1 to 3 and may be selected from the group consisting of tris(8-hydroxyquinoline)aluminum, triazine, hydroxyquinoline derivatives, benzazole derivatives and silole derivatives.

In addition, the n-type dopant d1 may be any one of an alkali metal, an alkaline earth metal, an alkali metal compound and an alkaline earth metal compound, or the n-type dopant may serve as an electron donor and may be an organic n-type dopant that can form a charge-transfer complex with the organic host.

In a case in which the n-type dopant d1 is the metal or the metal compound of the former, the n-type dopant d1 may include Li, Na, K, Rb, Cs, Mg, Ca, Sr, Ba, La, Ce, Nd, Sm, Eu, Tb, Dy, or Yb, or a compound thereof.

In a case in which the n-type dopant d1 is the organic n-type dopant of the latter, the n-type dopant d1 has a strong electron donor property and as a result, the n-type dopant donates at least a part of electric charges to the organic host h and thus forms a charge-transfer complex with the organic host. Non-limiting examples of the organic molecule of the n-type dopant include bis(ethylenedithio)tetrathiafulvalene (BEDT-TTF), tetrathiafulvalene (TTF), and derivatives thereof.

When the organic host h is a polymer, the n-type dopant may be the material described above, or may be a material molecularly dispersed or a minor component copolymerized with the host.

Meanwhile, a ratio of the n-type dopant in the organic host h is 0.1% to 15% by volume with respect to the total volume of the organic host. In addition, in the structure shown in FIG. 1, the n-type dopant d1 may be co-deposited together with the organic host h over the entire region, or may be supplied in a small amount only in a limited region only in the process of supplying the organic host h such that it is disposed adjacent to the electron transport layer 127 of the first stack.

Meanwhile, the p-type dopant d2 may be a metal oxide or an organic p-type dopant, and serve as an electron acceptor. If the p-type dopant is the organic p-type dopant, the p-type dopant can form a charge-transfer complex with the organic host.

In this case, when the p-type dopant d2 is an organic dopant, it may be a radialene compound represented by the following Formula 4:

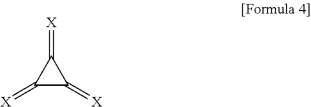

wherein X each independently represent

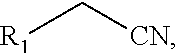

wherein R₁ are each independently selected from the group consisting of aryl and heteroaryl, wherein the aryl and heteroaryl are substituted by at least one electron acceptor group.

In this case, the electron acceptor group is selected from cyano, fluoro, trifluoromethyl, chloro and bromo. In addition, R₁ may be substituted by one of perfluoropyridin-4-yl, tetrafluoro-4-(trifluoromethyl)phenyl), 4-cyanoperfluorophenyl, dichloro-3,5-difluoror=4=(trifluoromethyl)phenyl, and perfluorophenyl.

In addition, when the p-type dopant d2 is an organic p-type dopant, the p-type dopant d2 preferably has a LUMO energy level between a highest occupied molecular orbital (HOMO) energy level of the organic host h and a lowest unoccupied molecular orbital (LUMO) energy level thereof and has a HOMO energy level lower than a HOMO energy. level of the p-type organic host.

In addition, when the p-type dopant is a metal compound, the metal in the metal compound has a work function lower than that of the metal or the metal compound used as the n-type dopant.

Like the n-type dopant, the p-type dopant is formed in an amount of 0.1% to 15% by volume with respect to the total volume of the charge generation layer 130 and is co-deposited together with the organic host h such that it is disposed adjacent to the hole transport layer 143 of the second stack of FIG. 1 or over the entire region of the charge generation layer 130.

The n-type dopant d1 and the p-type dopant d2 are supplied and co-deposited together with the organic host h upon formation of the charge generation layer 130 and may be disposed in different regions in the charge generation layer 130 while changing supply time. In some cases, when the p-type dopant d2 is disposed in the charge generation layer 130 such that it contacts the hole transport layer 143 of the second stack and the n-type dopant d1 is disposed in the charge generation layer 130 such it contacts the electron transport layer 127 of the first stack, the p-type dopant d2 may overlap the n-type dopant d1 in the charge generation layer 130, or the p-type dopant d2 and the n-type dopant d1 may be formed in separate regions such that the p-type dopant d2 does not overlap the n-type dopant d1 in the charge generation layer 130.

Meanwhile, white light can be emitted toward the cathode 150 or the anode 110 when the respective stacks include a blue stack and a phosphorescent stack emitting light having a longer wavelength than blue which are laminated in this order from the bottom.

In addition, as shown in the drawing, the anode 110 is adjacent to the substrate 100 and the plurality of stacks, the charge generation layer between the stacks and the cathode 150 disposed are formed thereon. In some cases, the cathode is provided adjacent to the substrate 100, the anode is provided such that the anode faces the cathode, and the charge generation layer is provided between the cathode and the anode in reverse order of the order shown in FIG. 1.

Here, the phosphorescent light emitting layer of the phosphorescent stack includes a host of at least one hole transport material and a host of at least one electron transport material, and includes a dopant which emits light having a wavelength of a yellow green or yellowish green region or a red green region.

In addition, one or two dopants may be contained in the phosphorescent emitting layer of the phosphorescent stack.

When two dopants are present, the dopants may be doped at different concentrations.

Meanwhile, in a case in which the first stack 120 is a blue stack, the first stack 120 includes a blue fluorescent emitting layer. In some cases, if development of materials is possible, the blue fluorescent emitting layer may be changed to a blue phosphorescent emitting layer.

In addition, one or two dopants may be contained in the phosphorescent emitting layer of the phosphorescent stack. When two dopants are present, the dopants may be doped at different concentrations. In this case, the respective dopants are not doped to thicknesses not more than 400 Å.

Meanwhile, the first stack 120 includes a blue fluorescent emitting layer 125. In some cases, if development of materials is possible, the blue fluorescent emitting layer may be changed to a blue phosphorescent emitting layer.

In addition, triplet levels of the hole transport layers 123 and 143 and the electron transport layers 127 and 147 adjacent to the light emitting layers 125 and 145 of the respective stacks 120 and 140 is preferably 0.01 to 0.4 eV higher than a triplet level of a host of the light emitting layer. This serves to prevent excitons generated in the respective light emitting layers from being transferred from the corresponding light emitting layer to the hole transport layer or the electron transport layer adjacent thereto.

Hereinafter, a principle of moving electrons and holes in Reference Example and the invention will be described with reference to the annexed drawings.

FIG. 2 is a view illustrating an energy bandgap between a charge generation layer and a layer adjacent thereto in Reference Example compared with the white organic light emitting device according to an embodiment of the invention.

As shown in FIG. 2, the white organic light emitting device of Reference Example includes an n-type charge generation layer 33 and a p-type charge generation layer 37 separately formed between different stacks and further includes an electron transport layer 27 of the first stack adjacent to the n-type charge generation layer 33 and a hole transport layer 43 of the second stack adjacent to the p-type charge generation layer 37.

Here, the n-type charge generation layer 33 includes an alkali metal as an n-type dopant and the p-type charge generation layer 37 includes an organic p-type dopant.

In this case, in a case in which electrons present at a position of the LUMO energy level of the p-type charge generation layer 37 are transferred to the n-type charge generation layer 33 at the interface between the n-type charge generation layer 33 and the p-type charge generation layer 37 which are separately formed, smooth transfer of the electrons is disadvantageously difficult due to large energy barrier and electrons are accumulated at the interface between the n-type charge generation layer 33 and the p-type charge generation layer 37.

For this reason, generation of holes in the p-type charge generation layer is inhibited due to insufficient electron transfer although n-type dopants are present in the n-type charge generation layer 33. This results in problems of deteriorated lifespan and increased driving voltage.

In addition, a fundamental problem of low yield of organic light emitting devices is generated when a plurality of interfaces are repeatedly present.

The embodiments of the invention described below are provided to solve this problem.

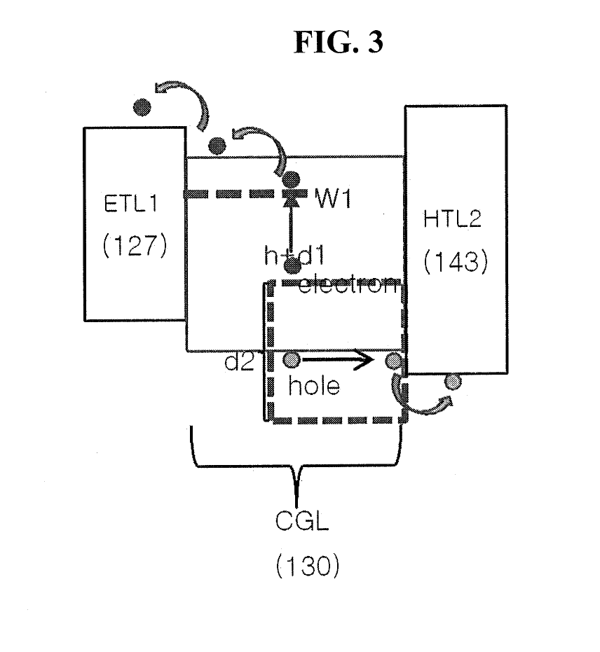

FIG. 3 is a view illustrating an energy bandgap between a charge generation layer and a layer adjacent thereto in a white organic light emitting device according to a first embodiment of the invention.

As shown in FIG. 3, the white organic light emitting device according to the first embodiment includes a charge generation layer which has a single layer structure, rather than a double layer structure and contains one organic host h, an n-type dopant d1 and a p-type dopant d2.

Here, the n-type dopant d1 is selected as a metal dopant including an alkali metal or an alkaline earth metal having a first work function.

In addition, the p-type dopant d2 is an example an organic p-type dopant and has a LUMO energy level (LUMO2) between a highest occupied molecular orbital (HOMO) energy level HOMO1 of the organic host h and a lowest unoccupied molecular orbital (LUMO) LUMO1 energy level thereof and has a HOMO energy level HOMO2 lower than a HOMO energy level of the p-type organic host. In addition, the organic p-type dopant is represented by the compound of Formula 4 described above.

Here, when the n-type dopant d1 is disposed adjacent to the hole transport layer 127 of the first stack closest to the charge generation layer 130, the p-type dopant d2 is disposed adjacent to the hole transport layer 143 of the second stack in the charge generation layer 130.

In this case, the charge generation layer is formed by co-depositing the n-type dopant d1 and the p-type dopant d2 in the single organic host h, thereby removing the interface separating the charge generation layer and improving yield as compared to Reference Example.

In addition, stepping transfer of electrons in the charge generation layer 130 is possible, thereby facilitating transfer of electrons from the charge generation layer 130 to the electron transport layer 127 of the first stack adjacent thereto. In addition, the p-type dopant d2 is co-doposited adjacent to the hole transport layer 143 of the second stack, thereby facilitating transfer of holes disposed at the HOMO energy level HOMO1 of the organic host to the hole transport layer 143 of the second stack.

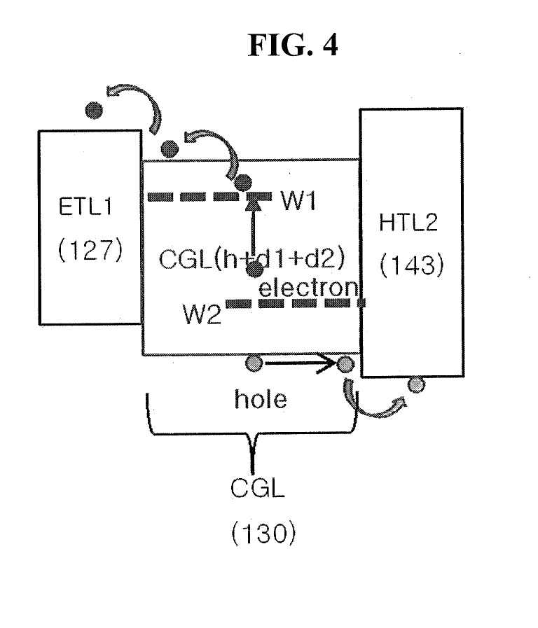

FIG. 4 is a view illustrating an energy bandgap between a charge generation layer and a layer adjacent thereto in a white organic light emitting device according to a second embodiment of the invention.

The second embodiment shown in FIG. 4 utilizes a metal component as the p-type dopant d2, compared to the first embodiment shown in FIG. 3 and the metal compound is for example W₂O₃, V₂O₅, or Mo₂O₃.

In addition, a work function W2 of the metal contained in the metal compound is lower than a work function W1 of the metal used as the n-type dopant so that electrons generated in the charge generation layer 230 are easily transferred from the work function W2 of the metal in the metal compound as the p-type dopant to the work function W1 of the metal as the n-type dopant and electrons are easily transferred from the charge generation layer 230 to the electron transport layer of the first stack due to slight difference between the work function W1 and LUMO of the electron transport layer of the adjacent first stack.

Furthermore, holes disposed at the HOMO energy level HOMO1 of the organic host are easily transferred to the hole transport layer 143 of the second stack.

Description of the features of the second embodiment the same as those of the first embodiment described above is omitted.

Hereinafter, evaluation of lifespan and luminance of Reference Example shown in FIGS. 2 and 3 and the first embodiment of the invention by experiments will be described below.

The first stacks described below in Reference Example and the first embodiment of the invention use a blue fluorescent emitting layer as a blue stack and the first stack is adjacent to the anode and includes a hole injection layer, a first hole transport layer, a blue fluorescent emitting layer and a first electron transport layer which are in common formed in this order.

In addition, the second stack is adjacent to the charge generation layer 130 or the p-type charge generation layer 37 and includes a second hole transport layer, a phosphorescent emitting layer, a second electron transport layer and an electron injection layer which are in common formed in this order. Here, a case in which the phosphorescent emitting layer is for example a yellow green phosphorescent emitting layer is tested.

In common, the hole injection layer of the first stack is formed using HAT-CN of Formula 5, and the first hole transport layer is formed using a material represented by Formula 6 below. In addition, the blue fluorescent emitting layer includes a host component of Formula 7 and a blue dopant of Formula 8. In addition, the second electron transport layer is then formed using a material represented by Formula 9.

In addition, the first embodiment of the white organic light emitting device according to the invention is different from Reference Example in that in the first embodiment, a charge generation layer is formed by co-deposition using a single host, and a combination of an n-type dopant and a p-type dopant, while in Reference Example, an n-type charge generation layer and a p-type charge generation layer are separately formed such that the n-type charge generation layer and the p-type charge generation layer has an n-type property and a p-type property, respectively.

That is, the organic substance of Formula 9 is used for the host material of the n-type charge generation layer of Reference Example and a small amount of alkali metal or alkaline earth metal such as Li or Mg is incorporated as the n-type dopant into the n-type charge generation layer.

In addition, only HAT-CN of Formula 5 is used for the organic host of the p-type charge generation layer formed in Reference Example.

On the other hand, the charge generation layer according to the invention utilizes an organic substance of Formula 9 as an organic host, a metal such as an alkali metal or alkaline earth metal as the n-type dopant, and a radialene compound of Formula 4 as the p-type dopant.

In addition, the second hole transport layer of the second stack formed in common in Reference Example and the first embodiment of the invention is formed using the same material of Formula 6 as the first hole transport layer of the first stack and the phosphorescent emitting layer is formed using the material of Formula 10 as a host and the material of Formula 11 as a yellow green dopant.

Then, the second electron transport layer is formed using the same material of Formula 9 as the first electron transport layer and the electron injection layer is formed using LiF.

Meanwhile, materials for respective layers of the first stack and the respective layers of the second stack, i.e., hole transport layers, light emitting layers and electron transport layers are not limited to those described above and are selected and changed in consideration of hole and electron transport properties. In addition, the dopant of the light emitting layer may be changed according to colors of emitted light required for respective stacks.

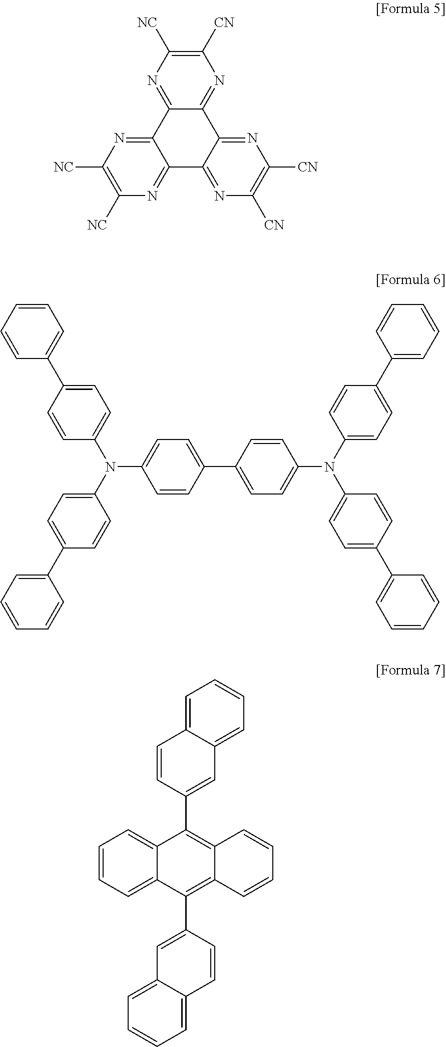

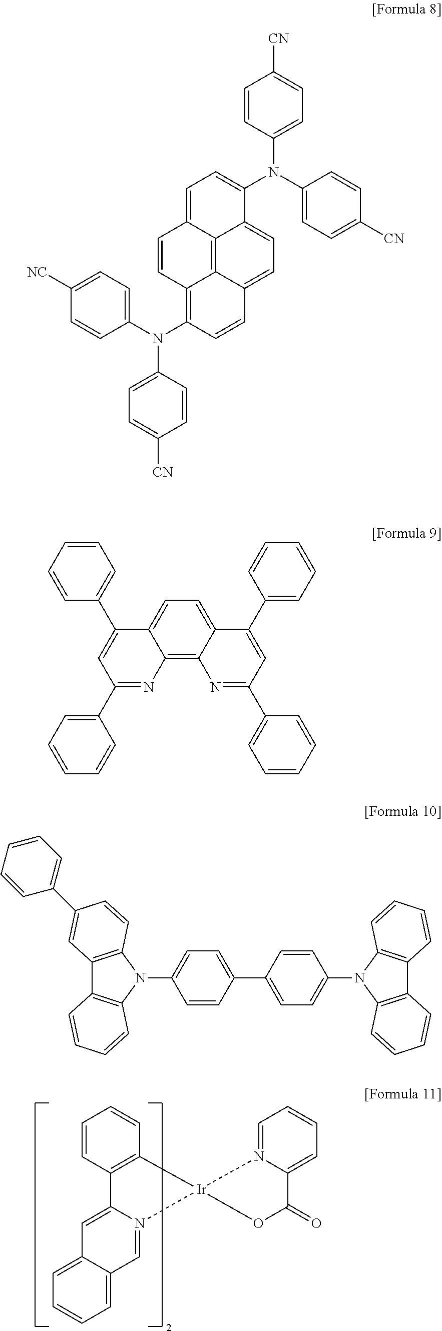

TABLE 1

| | | Voltage | Efficacy | T95 |
|---|---|---|---|---|
| | Charge generation layer structure | (V) | (Cd/A) | (hours) |
| Reference | n-type charge generation layer | 100% | 100% | 100% |
| Example | (host + n-type dopant)/p-type | | | |
| | charge generation layer (HAT- | | | |
| | CN) | | | |
| First | Charge generation layer (organic | 101% | 99.3% | 111% |
| embodiment | host + n-type dopant + p-type | | | |
| | dopant) | | | |

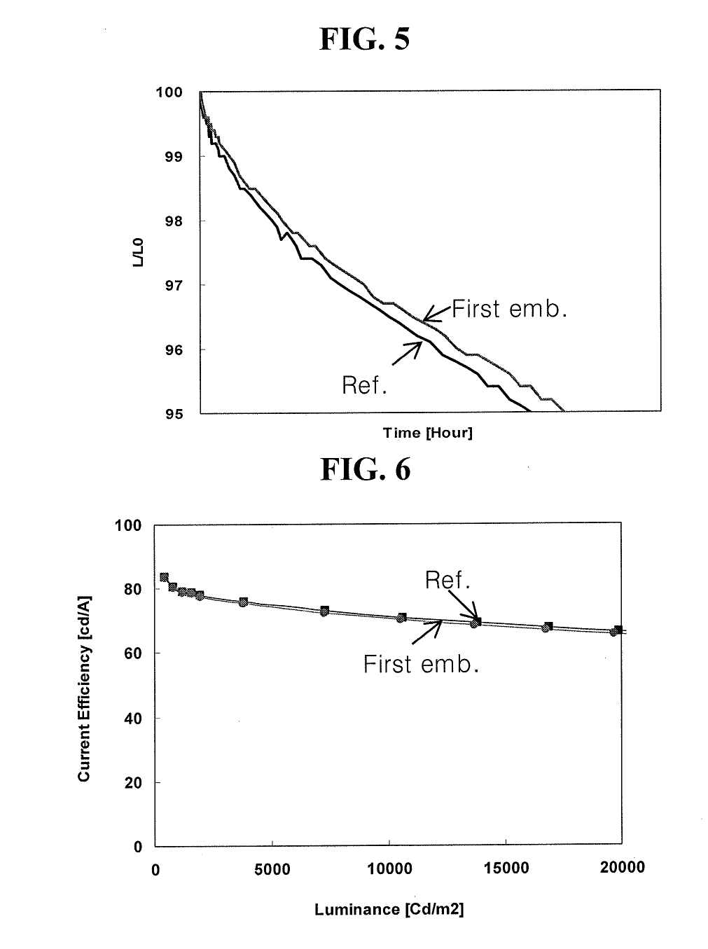

FIG. 5 is a graph showing comparison in lifespan between Reference Example and the embodiment of the invention and FIG. 6 is a graph showing current efficacy according to luminance in Reference Example and the embodiment of the invention.

As shown in FIG. 5 and Table 1, the first embodiment of the invention exhibits a time T95 taken until luminance L is varied to 95% of an initial luminance L0, of 111% which is 11% higher than Reference Example. Considering the fact that the difference in the time T95 therebetween increases as variation in luminance L from the initial luminance L0 increases, differences between the first embodiment and Reference Example in terms of times taken until luminance is decreased to initial luminance of 90%, 75% and 50% further increase. That is, the white organic light emitting device of the first embodiment of the invention is superior to Reference Example in terms of at least lifespan.

As can be seen from Table 1, regarding driving voltage or current efficiency, the first embodiment of the invention exhibits a slight increase (i.e., 101%) in driving voltage and a slight decrease (i.e., 99.3%) in efficacy as compared to Reference Example. These increase and decrease levels are substantially negligible, which means that Reference Example and the embodiment exhibit substantially similar driving voltage and efficacy. That is, the white organic light emitting device of the invention exhibits superior or similar voltage or efficacy as compared to Reference Example although a charge generation layer structure is simplified.

Meanwhile, the experiment described above is performed using the compound of Formula 1 for the organic host of the charge generation layer, but the invention is not limited thereto. The organic host may be changed to the material represented by Formula 2 or 3 and the p-type host may be also selected from compounds that can be represented by Formula 4.

That is, the white organic light emitting device of the invention includes a charge generation layer simplified into a single layer, instead of the charge generation layer having a double layer structure including an n-type charge generation layer and a p-type charge generation layer, thereby improving yield. For this purpose, the material for the organic host is selected such that two dopants having different types of polarities efficiently perform their functions in the charge generation layer. As a result, the interface between the n-type charge generation layer and the p-type charge generation layer is removed, thus providing effects of preventing an increase in driving voltage, improving lifespan and simplifying a layer structure.

The white organic light emitting device of the invention has the following effect.

The white organic light emitting device of the invention includes a charge generation layer simplified into a single layer, instead of the charge generation layer having a double layer structure including an n-type charge generation layer and a p-type charge generation layer, thereby improving yield. For this purpose, the material for the organic host is selected such that dopants having different types of polarities efficiently perform their functions in the charge generation layer. As a result, it makes to omit interfaces in the charge generation layer, thus it is possible to provide the effects of preventing an increase in driving voltage, improving lifespan and simplifying a layer structure.

It will be apparent to those skilled in the art that various modifications and variations can be made in the invention without departing from the spirit or scope of the inventions. Thus, it is intended that the invention covers the modifications and variations of this invention provided they come within the scope of the appended claims and their equivalents.

What is claimed is:

1. A white organic light emitting device comprising:
an anode and a cathode opposite to each other;
a plurality of stacks disposed between the anode and the cathode, each of the stacks including a hole transport layer, a light emitting layer and an electron transport layer; and
a charge generation layer disposed between different stacks, the charge generation layer including a single organic host having an electron transport property, an n-type dopant and a p-type dopant.

2. The white organic light emitting device according to claim 1, wherein the organic host has a lowest unoccupied molecular orbital (LUMO) energy level of −3.5 eV to −2.0 eV and a highest occupied molecular orbital (HOMO) energy level of −6.5 eV to −5.0 eV.

3. The white organic light emitting device according to claim 2, wherein the organic host has an electron mobility of 1.0×10⁻⁵ V·s/cm² to 5.0×10⁻³ V·s/cm².

4. The white organic light emitting device according to claim 1, wherein the n-type dopant is any one of an alkali metal, an alkaline earth metal, an alkali metal compound and an alkaline earth metal compound.

5. The white organic light emitting device according to claim 1, wherein the n-type dopant serves as an electron donor and is an organic n-type dopant which forms a charge-transfer complex with the organic host.

6. The white organic light emitting device according to claim 1, wherein the p-type dopant serves as an electron acceptor and is an organic p-type dopant which forms a charge-transfer complex with the organic host.

7. The white organic light emitting device according to claim 6, wherein the p-type dopant is a radialene compound represented by the following Formula: 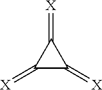
wherein X each independently represent 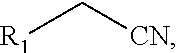
wherein R₁ are each independently selected from the group consisting of aryl and heteroaryl, wherein the aryl and heteroaryl are substituted by at least one electron acceptor group.

8. The white organic light emitting device according to claim 7, wherein the electron acceptor group is selected from cyano, fluoro, trifluoromethyl, chloro and bromo.

9. The white organic light emitting device according to claim 8, wherein R₁ is substituted by one of perfluoropyridin-4-yl, tetrafluoro-4-(trifluoromethyl)phenyl), 4-cyanoperfluorophenyl, dichloro-3,5-difluoror=4=(trifluoromethyl)phenyl, and perfluorophenyl.

10. The white organic light emitting device according to claim 1, wherein the n-type dopant and the p-type dopant are each formed in amounts of 0.1% to 15% by volume with respect to the total volume of the charge generation layer.

11. The white organic light emitting device according to claim 1, wherein the p-type dopant comprises metal oxide.

12. The white organic light emitting device according to claim 1, wherein the p-type dopant has a LUMO energy level between a HOMO energy level and a LUMO energy level of the organic host and has a HOMO energy level lower than a HOMO energy level of the p-type organic host.

13. The white organic light emitting device according to claim 1, wherein the charge generation layer is disposed between a first stack and a second stack adjacent to each other, and
the p-type dopant in the charge generation contacts the hole transport layer of the second stack, and the n-type dopant in the charge generation layer contacts the electron transport layer of the first stack.

14. The white organic light emitting device according to claim 1, wherein the p-type dopant overlaps the n-type dopant in the charge generation layer.

15. The white organic light emitting device according to claim 1, wherein the p-type dopant does not overlap the n-type dopant in the charge generation layer.
